(19) United States
(12) Patent Application Publication
(10) Pub. No.: US 2025/0336757 A1
(43) Pub. Date: Oct. 30, 2025

(54) CONCURRENT GENERAL-PURPOSE MEMORY DIE AND NEAR-MEMORY COMPUTE DIE IN SYSTEM-IN-PACKAGE (SIP)

(71) Applicant: QUALCOMM Incorporated, San Diego, CA (US)

(72) Inventors: Mustafa BADAROGLU, San Diego, CA (US); Zhongze WANG, San Diego, CA (US); Periannan CHIDAMBARAM, San Diego, CA (US); Roawen CHEN, San Diego, CA (US); Woo Tag KANG, San Diego, CA (US)

(21) Appl. No.: 18/650,269

(22) Filed: Apr. 30, 2024

(51) Int. Cl. H01L 23/373; H01L 23/00; H01L 23/538; H01L 25/065; H10B 80/00

(52) U.S. Cl. CPC H01L 23/3731; H01L 23/5389; H01L 24/32; H01L 24/48; H01L 24/73; H01L 25/0652; H01L 2224/32145; H01L 2224/32225; H01L 2224/48132; H01L 2224/48225; H01L 2224/73265; H01L 2924/1431; H01L 2924/1434; H01L 2924/182; H01L 2924/351; H10B 80/00

(57) ABSTRACT

A system-in-package (SIP) is described. The SIP includes a general-purpose memory die. The SIP also includes a near-memory compute die. The SIP further includes an inter-space filler in between the general-purpose memory die and the near-memory compute die.

### BACKGROUND

### Field

Aspects of the present disclosure relate to semiconductor devices and, more particularly, to a concurrent general-purpose memory die and a near-memory compute die in a system-in-package (SIP).

### Background

Memory is a vital component for wireless communications devices. For example, a cell phone may integrate memory as part of an application processor, such as a system-on-chip (SoC) including a central processing unit (CPU), a graphics processing unit (GPU), and a neural processing unit (NPU). Successful operation of some wireless applications depends on the availability of a higher-capacity and low-latency memory solution for scalability of CPU/GPU/NPU workload. A semiconductor memory device solution for providing a high-capacity, low-latency, and high-bandwidth memory is an existing goal for system designers.

Semiconductor memory devices include, for example, a static random-access memory (SRAM) and a dynamic random-access memory (DRAM). In practice, memory intensive applications (e.g., artificial intelligence (AI)) consume extensive amounts of DRAM. Near-memory and in-memory computing provide advantages in performance and power for memory-demanding workloads of AI applications, such as generative AI. Unfortunately, near-memory computing solutions incur significant overhead in terms of memory area, performance, and power penalty whenever the memory is used for general-purpose data operations. Additionally, near-memory computing solutions restrict the dataflow and specify placement of data in a memory bank close to a near-memory compute block. An integration solution that provides both general-purpose memory and near-memory compute for memory-intensive workloads is desired.

### SUMMARY

A system-in-package (SIP) is described. The SIP includes a general-purpose memory die. The SIP also includes a near-memory compute die. The SIP further includes an inter-space filler in between the general-purpose memory die and the near-memory compute die.

A method of fabricating a system-in-package (SIP) concurrent memory integration is described. The method includes stacking a near-memory compute die on a general-purpose memory die. The method also includes depositing an inter-space filler in between the general-purpose memory die and the near-memory compute die.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), which includes an integration of general-purpose memory die and near-memory compute die in a system-in-package (SIP), in accordance with various aspects of the present disclosure.

FIGS. 2A and 2B are block diagrams illustrating a system-in-package (SIP), which includes an integration of a near-memory compute die stacked on a general-purpose memory die in a package-on-package (POP) connected memory configuration, according to various aspects of the present disclosure.

FIG. 3 is a block diagram illustrating a system-in-package (SIP), which includes an integration of a near-memory compute die and a general-purpose memory die in a side-by-side memory configuration, according to various aspects of the present disclosure.

FIG. 4 is a block diagram illustrating a system-in-package (SIP), which includes an integration of a near-memory compute die stacked on a general-purpose memory die in a three-dimensional (3D) stacked memory configuration, according to various aspects of the present disclosure.

FIGS. 5A-5C are schematic diagrams illustrating cross-sectional views of independent channel access to near-memory compute die and general-purpose memory die integrations, according to various aspects of the present disclosure.

FIG. 6 is a schematic diagram illustrating a cross-sectional view of a stacked memory integration including side-by-side placement of the stacked memory integration of FIG. 5A and the stacked memory configuration of FIG. 5B on a base die, according to various aspects of the present disclosure.

FIGS. 7A-7D are schematic diagrams illustrating cross-sectional views of a process for fabrication of near-memory compute die and general-purpose memory die integration, according to various aspects of the present disclosure.

FIG. 8 is a process flow diagram illustrating a method for fabricating a system-in-package (SIP) concurrent memory integration, according to various aspects of the present disclosure.

FIG. 9 is a block diagram showing an exemplary wireless communications system in which a configuration of the disclosure may be advantageously employed.

FIG. 10 is a block diagram illustrating a design workstation used for circuit, layout, and logic design of a semiconductor component, such as the general-purpose memory die/near-memory compute die integration disclosed herein.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches, repeaters, and/or buffers. As described herein, the term “proximate” used throughout this description means “adjacent, very near, next to, or close to.” As described herein, the term “on” used throughout this description means “directly on” in some configurations, and “indirectly on” in other configurations. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms “chip” and “die” may be used interchangeably.

Memory is a vital component for processing systems, such as wireless communications devices. For example, a cell phone may integrate memory as part of an application processor, such as a system-on-chip (SoC) including a central processing unit (CPU), a graphics processing unit (GPU), and a neural processing unit (NPU). Successful operation of some wireless applications depends on the availability of a higher-capacity and low-latency memory solution for scalability of CPU/GPU/NPU workload. A semiconductor memory device solution for providing a high-capacity, low-latency, and high-bandwidth memory is an existing goal for system designers.

Semiconductor memory devices include, for example, a static random-access memory (SRAM) and a dynamic random-access memory (DRAM). In practice, memory intensive applications (e.g., artificial intelligence (AI)) consume extensive amounts of DRAM. Near-memory and in-memory computing provide advantages in performance and power for memory-demanding workloads of AI applications, such as generative AI. Unfortunately, near-memory computing solutions incur significant overhead in terms of memory area, performance, and power penalty whenever the memory is used for general-purpose data operations. Additionally, near-memory computing solutions restrict the dataflow and specify placement of data in a memory bank close to a near-memory compute block. An integration solution that provides both general-purpose memory and near-memory compute for memory-intensive workloads is desired.

Various aspects of the present disclosure are directed to a concurrent general-purpose memory die and a near-memory compute die in a system-in-package (SIP). According to various aspects of the present disclosure, an inter-space filler is provided between the general-purpose memory die and the near-memory compute die. In this configuration, the inter-space filler accommodates general-purpose memory dies and near-memory compute dies of different dimensions. This concurrent general-purpose memory die and near-memory compute die SIP integration enables concurrent random data access to the general-purpose memory die while executing memory-stationary workloads such as generative AI at the near-memory compute die. This SIP memory integration provides a solution to tackle varied sizes such as large memory dies with near-memory computing and conventional memory dies.

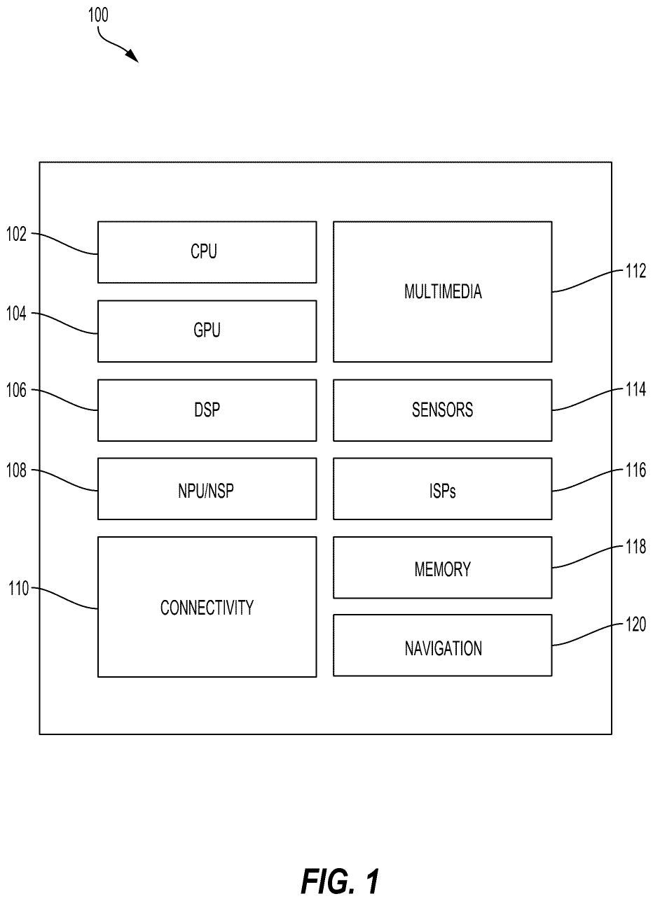

FIG. 1 illustrates an example implementation of a host system-on-chip (SoC) 100, which includes an integration of general-purpose memory die and near-memory compute die in a system-in-package (SIP), in accordance with aspects of the present disclosure. The host SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU)/neural signal processor (NSP) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU/NSP 108, and the multimedia engine 112 support various functions such as video, audio, graphics, gaming, artificial networks, and the like. Each processor core of the multi-core CPU 102 may be a reduced instruction set computing (RISC) machine, an advanced RISC machine (ARM), a microprocessor, or some other type of processor. The NPU/NSP 108 may be based on an ARM instruction set.

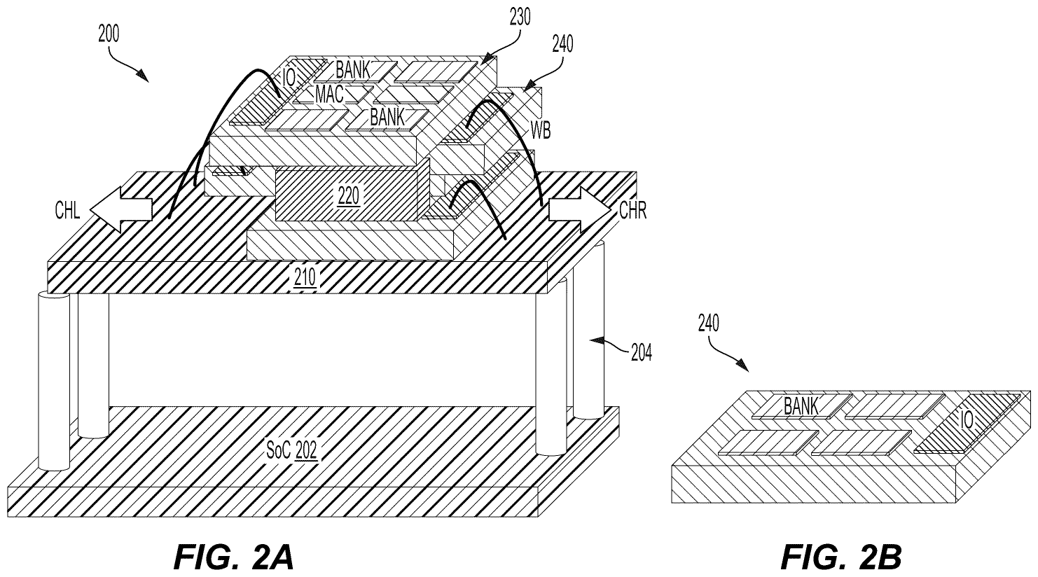

FIGS. 2A and 2B are block diagrams illustrating a system-in-package (SIP), which includes an integration of a near-memory compute die stacked on a general-purpose memory die in a package-on-package (POP) connected memory configuration, according to various aspects of the present disclosure. As shown in FIG. 2A, an SIP 200 is shown in a POP connected memory configuration, in which a system-on-chip (SoC) package 202 supports a substrate/interposer 210 using conductive interconnects 204 (e.g., copper (Cu) pillars). In various aspects of the present disclosure, the substrate/interposer 210 supports integration of a near-memory compute die 230 stacked on general-purpose memory dies 240, having an inter-space filler 220 between the near-memory compute die 230 and the general-purpose memory dies 240.

In this example, the near-memory compute die 230 includes an input/output (IO) block, memory banks (BANK), and multiply-accumulate (MAC) compute blocks. FIG. 2B further illustrates the general-purpose memory die 240, including an IO block and memory banks (BANK), as well as wire bonds (WB) coupled between the IO blocks and the substrate/interposer 210. As shown in FIG. 2A, wire bonds (WB) are coupled between the IO blocks of both the near-memory compute die 230 and general-purpose memory dies 240 and the substrate/interposer 210. The SIP 200 is configured in the POP connected memory configuration, which provides right memory channels (CHR) and left memory channels (CHL) to enable concurrent memory operation. In particular, the POP connected memory configuration of the SIP 200 enables concurrent random data access to the general-purpose memory die 240 while executing memory-stationary workloads such as generative AI at the near-memory compute die 230. This memory integration provided by the SIP 200 offers a solution to integrate different sized near-memory computing dies and conventional memory dies. As described in further detail below, the inter-space filler 220 may be implemented using an embedded molding compound (EMC) composed of a thermally conductive material (TMC).

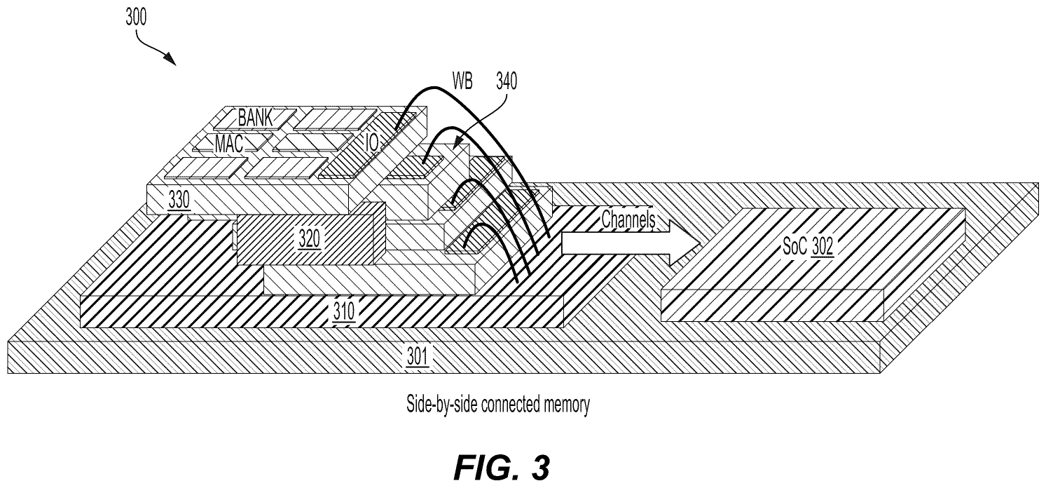

FIG. 3 is a block diagram illustrating a system-in-package (SIP), which includes an integration of a near-memory compute die and a general-purpose memory die in a side-by-side memory configuration, according to various aspects of the present disclosure. In FIG. 3 an SIP 300 is shown in a side-by-side connected memory configuration, in which a system-on-chip (SoC) package 302 and a substrate/interposer 310 are supported by a package substrate 301. In various aspects of the present disclosure, the substrate/interposer 310 supports integration of a near-memory compute die 330 stacked on one or more general-purpose memory dies 340, having an inter-space filler 320 between the near-memory compute die 330 and the general-purpose memory dies 340.

In this example, the near-memory compute die 330 also includes an input/output (IO) block, memory banks (BANK), and multiply-accumulate (MAC) compute blocks. The general-purpose memory dies 340 also include IO blocks and memory banks (BANK), as well as wire bonds (WB) coupled between the IO blocks and the substrate/interposer 310. The near-memory compute die 330 is also shown with a WB coupled between the IO block and the substrate/interposer 210. As shown in FIG. 3, the SIP 300 is configured in a side-by-side connected memory configuration, in which channels are provided to enable concurrent memory operation. In particular, the side-by-side connected memory configuration of the SIP 300 enables concurrent random data access to the general-purpose memory dies 340 while executing memory-stationary workloads, such as generative AI at the near-memory compute die 330, which has a different size from the general-purpose memory dies 340. For example, the general-purpose memory die 340 has a first size and the near-memory compute die 330 has a second size different from the first size (e.g., smaller). The inter-space filler 320 may be implemented using an embedded molding compound (EMC) composed of a thermally conductive material (TMC), an oxide, an underfill material (e.g., UF1), a non-conductive film (NCF), and/or spin-on underfill for micro-bump implementations.

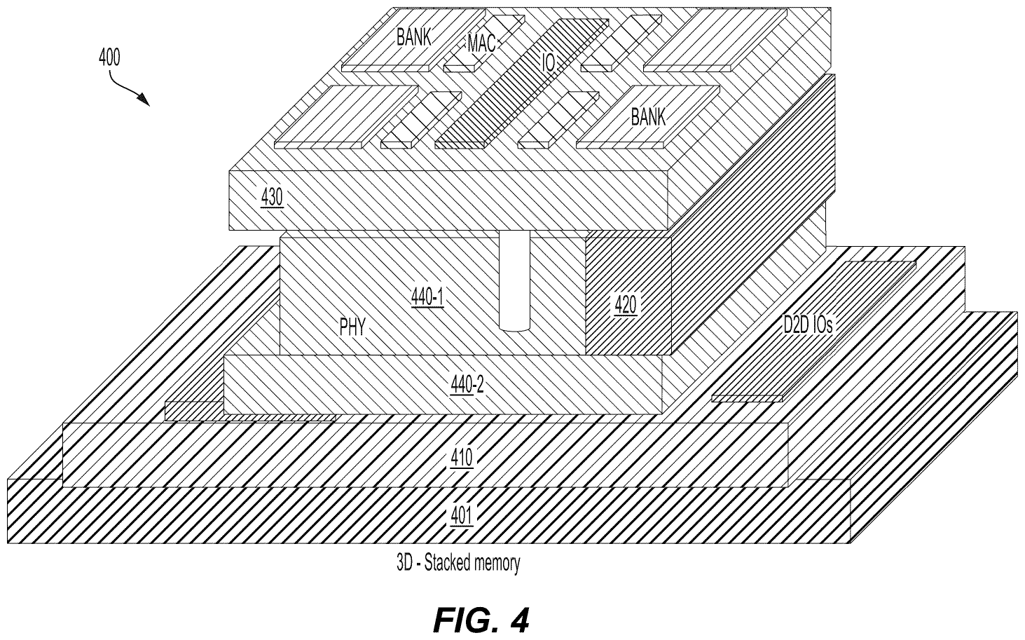

FIG. 4 is a block diagram illustrating a system-in-package (SIP), which includes an integration of a near-memory compute die stacked on a general-purpose memory die in a three-dimensional (3D) stacked memory configuration, according to various aspects of the present disclosure. As shown in FIG. 4, an SIP 400 is shown in a 3D stacked memory configuration, in which a base wafer/substrate/interposer 410 (e.g., a base die) is supported by a package substrate 401. In various aspects of the present disclosure, the base wafer/substrate/interposer 410 supports integration of a near-memory compute die 430 stacked on a general-purpose memory dies 440 (440-1, 440-2), having an inter-space filler 420 between the near-memory compute die 430 and the general-purpose memory die 440.

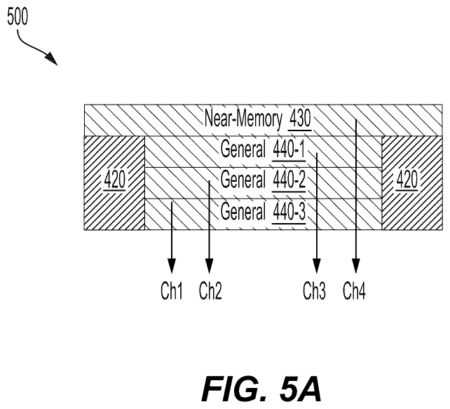

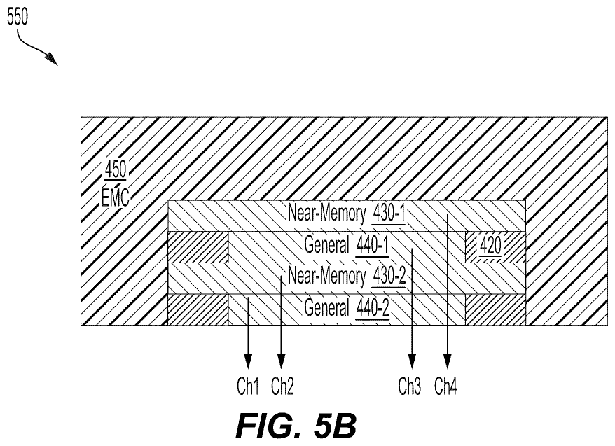

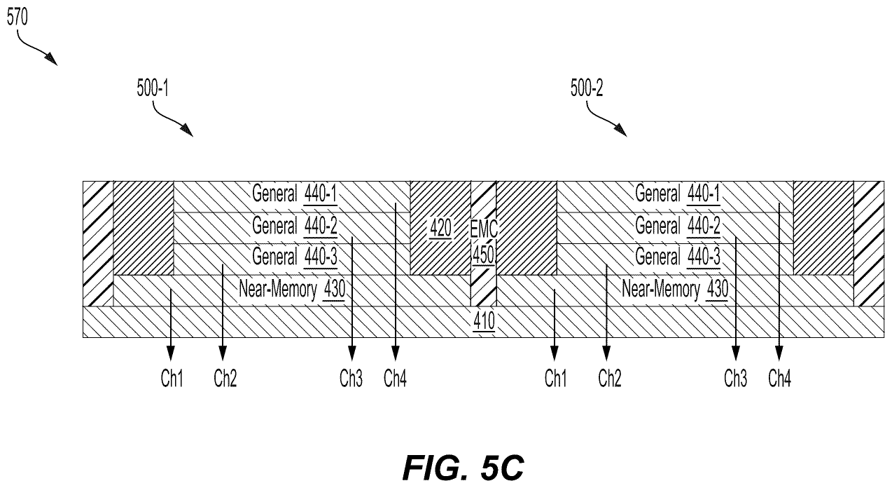

In this example, the near-memory compute die 430 also includes an input/output (IO) block, memory banks (BANK), and multiply-accumulate (MAC) compute blocks (blocks not labeled). The general-purpose memory die 440 also includes an IO block and memory banks (BANK) (blocks not labeled). As shown in FIG. 4, the SIP 400 is configured in a three-dimensional (3D) stacked memory configuration to enable concurrent memory operation. In particular, the 3D stacked memory configuration of the SIP 400 enables concurrent random data access to the general-purpose memory die 440 while executing memory-stationary workloads such as generative AI at the near-memory compute die 430, having a larger size than the general-purpose memory die 440 (e.g., smaller). The inter-space filler 420 may be implemented using an embedded molding compound (EMC) composed of a thermally conductive material (TMC), an oxide, an underfill material (e.g., UF1), a non-conductive film (NCF), and/or a spin-on underfill for micro-bump implementations, as further illustrated, for example, in FIGS. 5A-7D.

FIGS. 5A-5C are schematic diagrams illustrating cross-sectional views of independent channel access to near-memory compute die and general-purpose memory die integrations, according to various aspects of the present disclosure. As shown in FIG. 5A, a stacked memory integration 500 including the near-memory compute die 430 is stacked on one or more general-purpose memory dies 440 (in the current example, three general-purpose memory dies 440-1, 440-2, and 440-3), including the inter-space filler 420. According to various aspects of the present disclosure, the stacked memory integration 500 provides independent channel access (e.g., Ch1, Ch2, Ch3, Ch4) to the near-memory compute die 430 and the general-purpose memory dies 440. In particular, the stacked memory integration 500 enables concurrent random data access to the general-purpose memory dies 440 while executing memory-stationary workloads such as generative AI at the near-memory compute die 430.

As shown in FIG. 5B, a stacked memory integration 550 including near-memory compute dies 430 (430-1, 430-2) stacked with general-purpose memory dies 440 (440-1, 440-2), including an inter-space filler 420. According to various aspects of the present disclosure, the stacked memory integration 550 provides independent channel access (e.g., Ch1, Ch2, Ch3, Ch4) to the near-memory compute dies 430 and the general-purpose memory dies 440. The stacked memory integration 550 also enables concurrent random data access to the general-purpose memory dies 440 while executing memory-stationary workloads such as generative AI at the near-memory compute dies 430, having assorted sizes. In this example, an embedded molding compound (EMC) 450 is deposited on the stacked memory integration 550.

As shown in FIG. 5C, a stacked memory integration 570 including side-by-side placement of the stacked memory integration 500 of FIG. 5A on a base wafer/substrate/interposer 410 (e.g., a base die), according to various aspects of the present disclosure. In this example, the inter-space filler 420 is disposed between a first stacked memory integration 500-1 and a second stacked memory integration 500-2. In this example, embedded molding compound (EMC) 450 is deposited between the inter-space filler 420 on the first stacked memory integration 500-1 and the inter-space filler 420 on the second stacked memory integration 500-2.

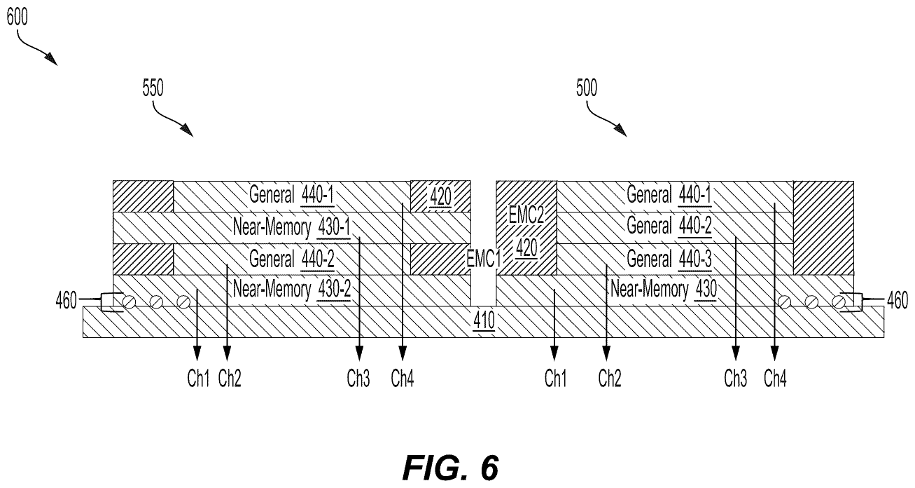

FIG. 6 is a schematic diagram illustrating a cross-sectional view of a stacked memory integration 600 including side-by-side placement of the stacked memory integration 500 of FIG. 5A and the stacked memory integration 550 of FIG. 5B on a base wafer/substrate/interposer 410 (e.g., a base die), according to various aspects of the present disclosure. In this example, an inter-space filler 420 is disposed between the stacked memory integration 500 of FIG. 5A and the stacked memory integration 550 of FIG. 5B. In this example, the inter-space filler 420 is composed of embedded molding compounds (e.g., EMC1 and EMC2). Additionally, the stacked memory integration 500 and the stacked memory integration 550 are secured to the base wafer/substrate/interposer 410 using micro-bumps 460. In this example, the inter-space filler 420 may be implemented using the same or different EMCs (e.g., EMC1 and EMC2) that may be composed of a thermally conductive material (TMC), an oxide, an underfill material (e.g., UF1), and/or a non-conductive film (NCF). A spin-on underfill implementation for the inter-space filler 420 is also possible due to the micro-bumps 460.

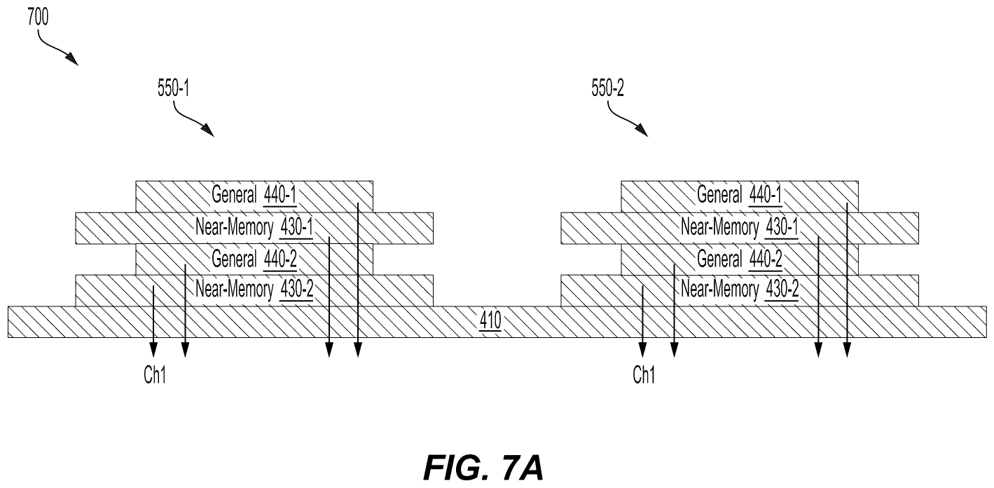

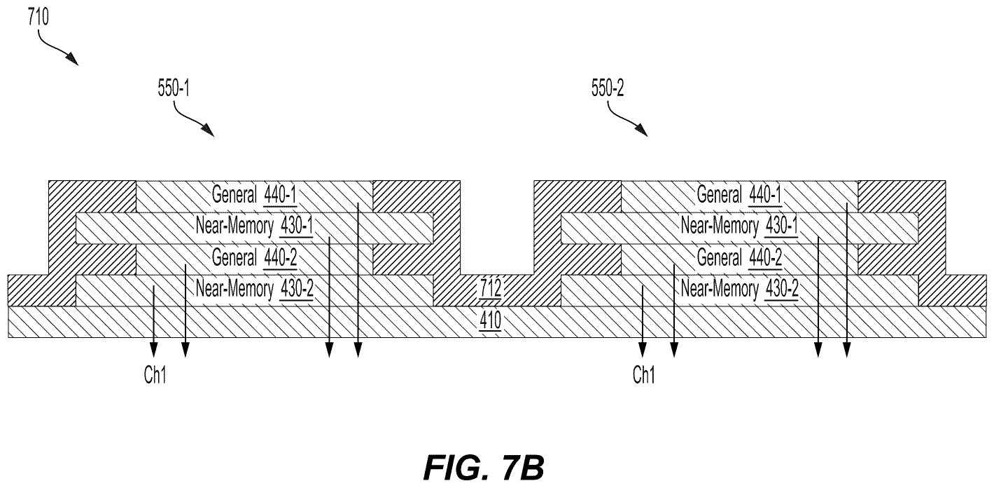

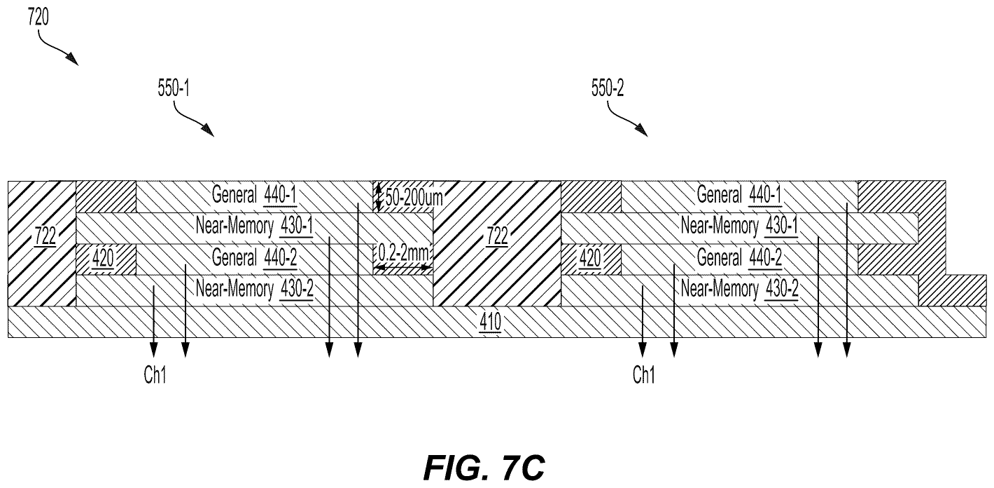

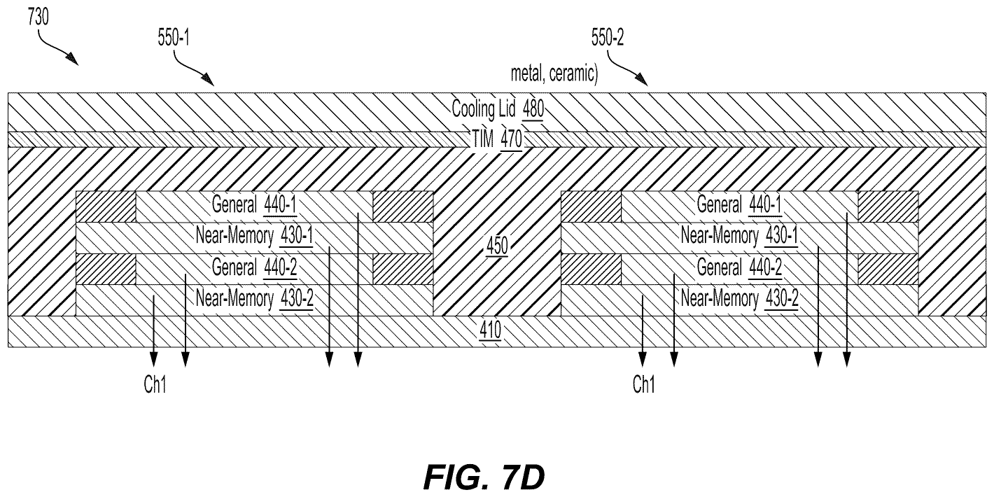

FIGS. 7A-7D are schematic diagrams illustrating cross-sectional views of a process for fabrication of near-memory compute die and general-purpose memory die integration, according to various aspects of the present disclosure. As shown in FIG. 7A, at step 700, a side-by-side placement of the stacked memory integration 550 of FIG. 5B is bonded to a base wafer/substrate/interposer 410 using a die-to-wafer (D2 W) stacking, according to various aspects of the present disclosure. In this example, a first stacked memory integration 550-1 and a second stacked memory integration 550-2 are stacked on the base wafer/substrate/interposer 410.

As shown in FIG. 7B, at step 710, a conformal material 712 is deposited between and on sidewalls of the first stacked memory integration 550-1 and the second stacked memory integration 550-2 (of FIG. 5B) and on the base wafer/substrate/interposer 410. For example, a physical vapor deposition (PVD) process in combination with a conformal dry process (e.g., gas state) is performed to deposit the conformal material 712. Additionally, the conformal material 712 may be composed of a thermally conductive EMC (e.g., epoxy resin, fused silica as a filler, hardener resin, cure promoter, coupling agent, flame retardant, other additives) an SoC (spin-on-carbon), an oxide, or other like thermally conductive material (TCM).

As shown in FIG. 7C, at step 720, the conformal material 712 deposited on the sidewalls of the first stacked memory integration 550-1 and the second stacked memory integration 550-2 is subjected to a sidewall trim etch to expose the base wafer/substrate/interposer 410 through openings 722. The sidewall trim etch of the conformal material 712 forms the inter-space filler 420, which may be composed of a spin-on-carbon, an oxide, a thermally conductive material (TCM), or other like conformal material. FIG. 7C further illustrates approximate height (50-200 microns) and width (0.2-2.2 millimeters (mm)) dimensions between the dies of the first stacked memory integration 550-1 and the second stacked memory integration 550-2.

As shown in FIG. 7D, at step 730, a spatial fill of the EMC 450 is performed to fill the opening on the first stacked memory integration 550-1 and the second stacked memory integration 550-2. In this example, the EMC 450 is deposited between the inter-space filler 420 on the first stacked memory integration 550-1 and the inter-space filler 420 on the second stacked memory integration 550-1. For example, the EMC 450 is composed of a thermally conductive EMC (e.g., epoxy resin, fused silica as a filler, hardener resin, cure promoter, coupling agent, flame retardant, other additives), a spin-on-carbon, an oxide, or other like thermally conductive material (TCM).

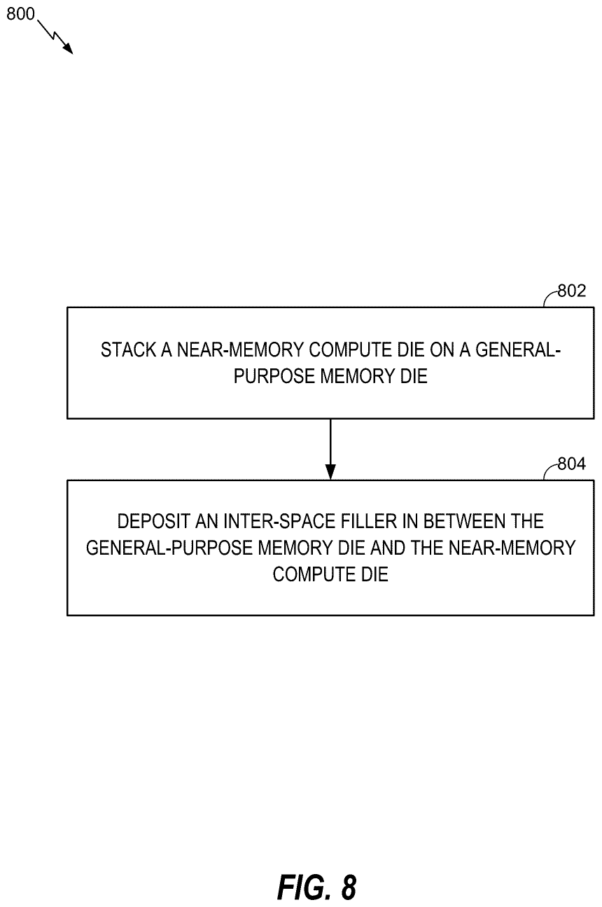

As further illustrated FIG. 7D, at step 730, a thermally insulative material (TIM) layer 470 (e.g., glue) is deposited on the EMC 450. Additionally, a cooling lid 480 (e.g., metal, ceramic) is formed on the TIM layer 470. This concurrent general-purpose memory die and near-memory compute die system-in-package (SIP) integration shown in FIG. 7D enables concurrent random data access to the general-purpose memory dies 440 while executing memory-stationary workloads such as generative AI at the near-memory compute dies 430. This concurrent memory integration provides a solution to tackle assorted sizes such as large memory dies with near-memory computing and conventional memory dies. A process of fabricating an SIP concurrent memory integration is illustrated, for example, in FIG. 8.

FIG. 8 is a process flow diagram illustrating a method 800 for fabricating a system-in-package (SIP) concurrent memory integration, according to various aspects of the present disclosure. The method 800 begins at block 802, in which a general-purpose memory die is stacked on a near-memory compute die. For example, as shown in FIG. 7A, at step 700, a side-by-side placement of the stacked memory integration 550 of FIG. 5B is bonded to a base wafer/substrate/interposer 410 using a die-to-wafer (D2 W) stacking, according to various aspects of the present disclosure. In this example, a first stacked memory integration 550-1 and a second stacked memory integration 550-2 are stacked on the base wafer/substrate/interposer 410.

At block 804, an inter-space filler is deposited between the general-purpose memory die and the near-memory compute die. For example, as shown in FIG. 7B, the conformal material 712 is deposited between and on sidewalls of the first stacked memory integration 550-1 and the second stacked memory integration 550-2 (of FIG. 5B) and on the base wafer/substrate/interposer 410. For example, a physical vapor deposition (PVD) process in combination with a conformal dry process (e.g., gas state) is performed to deposit the conformal material 712. Additionally, the conformal material 712 may be composed of a thermally conductive EMC (e.g., epoxy resin, fused silica as a filler, hardener resin, cure promoter, coupling agent, flame retardant, other additives) a spin-on-carbon, an oxide, or other like thermally conductive material (TCM).

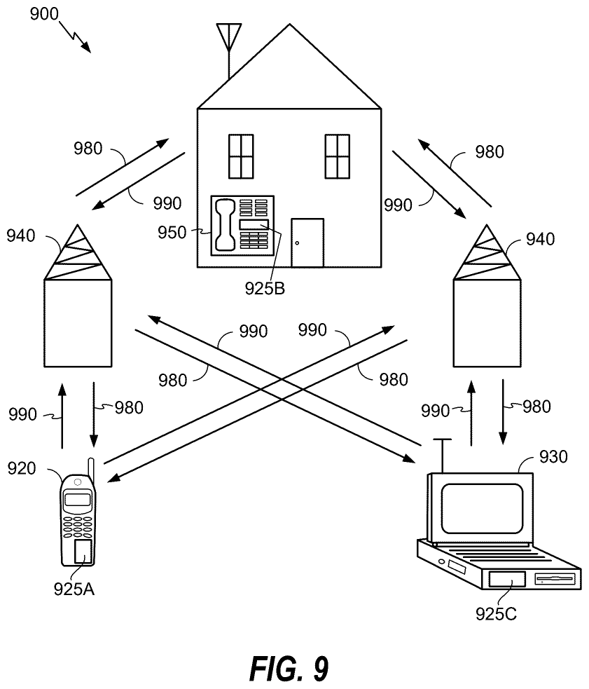

FIG. 9 is a block diagram showing an exemplary wireless communications system 900 in which a configuration of the disclosure may be advantageously employed. For purposes of illustration, FIG. 9 shows three remote units 920, 930, and 950, and two base stations 940. It will be recognized that wireless communications systems may have many more remote units and base stations. Remote units 920, 930, and 950 include integrated circuit (IC) devices 925A, 925C, and 925B that include the disclosed general-purpose memory die/near-memory compute die integration. It will be recognized that other devices may also include the disclosed general-purpose memory die/near-memory compute die integration, such as the base stations, switching devices, and network equipment. FIG. 9 shows forward link signals 980 from the base stations 940 to the remote units 920, 930, and 950, and reverse link signals 990 from the remote units 920, 930, and 950 to the base stations 940.

In FIG. 9, remote unit 920 is shown as a mobile telephone, remote unit 930 is shown as a portable computer, and remote unit 950 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 9 illustrates remote units according to aspects of the present disclosure, the disclosure is not limited to these exemplary illustrated units. Aspects of the present disclosure may be suitably employed in many devices, which include the disclosed general-purpose memory die/near-memory compute die integration.

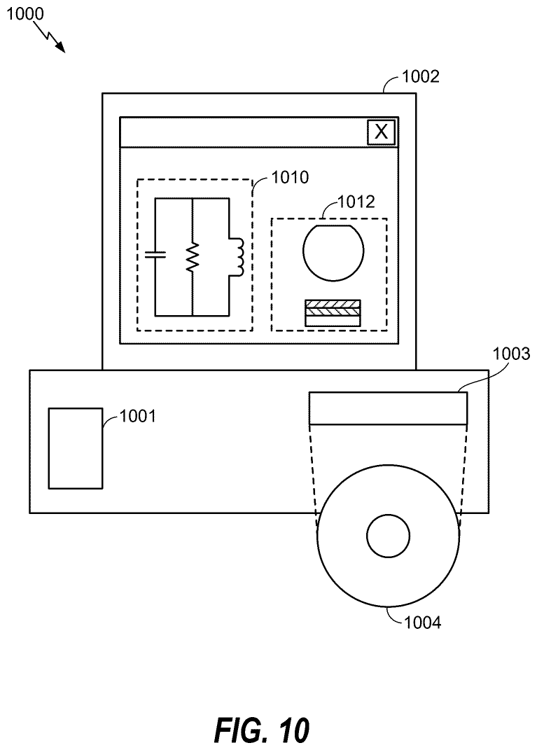

FIG. 10 is a block diagram illustrating a design workstation used for circuit, layout, and logic design of a semiconductor component, such as the general-purpose memory die/near-memory compute die integration disclosed above. A design workstation 1000 includes a hard disk 1001 containing operating system software, support files, and design software such as Cadence or OrCAD. The design workstation 1000 also includes a display 1002 to facilitate design of a circuit 1010 or an integrated circuit (IC) component 1012, such as a general-purpose memory die/near-memory compute die integration. A storage medium 1004 is provided for tangibly storing the design of the circuit 1010 or the IC component 1012 (e.g., the DRAM/SRAM SOC integration). The design of the circuit 1010 or the IC component 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the IC component 1012 by decreasing the number of processes for designing semiconductor wafers.

Implementation examples are described in the following numbered clauses:
1. A system-in-package (SIP), comprising:
a general-purpose memory die;
a near-memory compute die; and
an inter-space filler in between the general-purpose memory die and the near-memory compute die.
2. The SIP of clause 1, in which the general-purpose memory die having a first size and the near-memory compute die having a second size different from the first size.
3. The SIP of any of clauses 1 or 2, further comprising a base die supporting the general-purpose memory die and the near-memory compute die.
4. The SIP of any of clauses 1 or 2, further comprising a wafer/substrate/interposer supporting the general-purpose memory die and the near-memory compute die.
5. The SIP of any of clauses 1-4, in which the near-memory compute die is stacked on the general-purpose memory die, wherein the general-purpose memory die and the near-memory compute die at least partially overlap with each other.
6. The SIP of any of clauses 1-5, in which the inter-space filler comprises a thermally conductive material.
7. The SIP of any of clauses 1-5, in which the inter-space filler comprises a spin-on-carbon material.
8. The SIP of any of clauses 1-7, further comprising:
an embedded molding compound (EMC) on the inter-space filler and on sidewalls of the near-memory compute die;
a thermally insulative material (TIM) layer on the EMC; and
a conductive/ceramic material layer on the TIM layer.
9. The SIP of any of clauses 1-8, in which the near-memory compute die comprises multiply-accumulate (MAC) compute blocks.
10. The SIP of any of clauses 1-9, further comprising a system-on-chip (SoC) communicably coupled to the general-purpose memory die.
11. A method of fabricating a system-in-package (SIP) concurrent memory integration, the method comprising:
stacking a near-memory compute die on a general-purpose memory die; and
depositing an inter-space filler in between the general-purpose memory die and the near-memory compute die.
12. The method of clause 11, in which the general-purpose memory die having a first size and the near-memory compute die having a second size different from the first size.
13. The method of any of clauses 11 or 12, further comprising supporting the general-purpose memory die and the near-memory compute die with a base die.
14. The method of any of clauses 11 or 12, further comprising supporting the general-purpose memory die and the near-memory compute die with a wafer/substrate/interposer.
15. The method of any of clauses 11-14, in which depositing the inter-space filler further comprises:
conformally depositing a conformal material between the general-purpose memory die and the near-memory compute die and on a wafer/substrate/interposer supporting the general-purpose memory die and the near-memory compute die; and
performing a sidewall trim etch to expose the base wafer/substrate/interposer through openings and sidewalls of the near-memory compute die.
16. The method of clause 15, further comprising:
depositing an embedded molding compound (EMC) on the inter-space filler, on sidewalls of the near-memory compute die and on an exposed surface of the base wafer/substrate/interposer;
depositing a thermally insulative material (TIM) layer on the EMC; and
depositing a thermal/conductive material on the TIM.
17. The method of clause 15, in which the conformal material comprises a thermally conductive material.
18. The method of clause 15, in which the conformal material comprises a spin-on-carbon material.
19. The method of any of clauses 11-18, in which the near-memory compute die comprises multiply-accumulate (MAC) compute blocks.
20. The method of any of clauses 11-19, further comprising communicably coupling a system-on-chip (SoC) to the general-purpose memory die.

For a firmware and/or software implementation, the methodologies may be implemented with modules (e.g., procedures, functions, etc.) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A system-in-package (SIP), comprising:
a general-purpose memory die;
a near-memory compute die; and
an inter-space filler in between the general-purpose memory die and the near-memory compute die.

2. The SIP of claim 1, in which the general-purpose memory die having a first size and the near-memory compute die having a second size different from the first size.

3. The SIP of claim 1, further comprising a base die supporting the general-purpose memory die and the near-memory compute die.

4. The SIP of claim 1, further comprising a wafer/substrate/interposer supporting the general-purpose memory die and the near-memory compute die.

5. The SIP of claim 1, in which the near-memory compute die is stacked on the general-purpose memory die, wherein the general-purpose memory die and the near-memory compute die at least partially overlap with each other.

6. The SIP of claim 1, in which the inter-space filler comprises a thermally conductive material.

7. The SIP of claim 1, in which the inter-space filler comprises a spin-on-carbon material.

8. The SIP of claim 1, further comprising:
an embedded molding compound (EMC) on the inter-space filler and on sidewalls of the near-memory compute die;
a thermally insulative material (TIM) layer on the EMC; and
a conductive/ceramic material layer on the TIM layer.

9. The SIP of claim 1, in which the near-memory compute die comprises multiply-accumulate (MAC) compute blocks.

10. The SIP of claim 1, further comprising a system-on-chip (SoC) communicably coupled to the general-purpose memory die.

11. A method of fabricating a system-in-package (SIP) concurrent memory integration, the method comprising:
stacking a near-memory compute die on a general-purpose memory die; and
depositing an inter-space filler in between the general-purpose memory die and the near-memory compute die.

12. The method of claim 11, in which the general-purpose memory die having a first size and the near-memory compute die having a second size different from the first size.

13. The method of claim 11, further comprising supporting the general-purpose memory die and the near-memory compute die with a base die.

14. The method of claim 11, further comprising supporting the general-purpose memory die and the near-memory compute die with a wafer/substrate/interposer.

15. The method of claim 11, in which depositing the inter-space filler further comprises:
conformally depositing a conformal material between the general-purpose memory die and the near-memory compute die and on a wafer/substrate/interposer supporting the general-purpose memory die and the near-memory compute die; and
performing a sidewall trim etch to expose the base wafer/substrate/interposer through openings and sidewalls of the near-memory compute die.

16. The method of claim 15, further comprising:
depositing an embedded molding compound (EMC) on the inter-space filler, on sidewalls of the near-memory compute die and on an exposed surface of the base wafer/substrate/interposer;
depositing a thermally insulative material (TIM) layer on the EMC; and
depositing a thermal/conductive material on the TIM.

17. The method of claim 15, in which the conformal material comprises a thermally conductive material.

18. The method of claim 15, in which the conformal material comprises a spin-on-carbon material.

19. The method of claim 11, in which the near-memory compute die comprises multiply-accumulate (MAC) compute blocks.

20. The method of claim 11, further comprising communicably coupling a system-on-chip (SoC) to the general-purpose memory die.
